(19) United States
(12) Patent Application Publication
(10) Pub. No.: US 2005/0082592 A1
(43) Pub. Date: Apr. 21, 2005

(54) Compact capacitor structure having high unit capacitance

(75) Inventors: Chung Long Chang, Hsin-Chu (TW); Chun-Hon Chen, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co., Ltd., Hsin-Chu (TW)

(21) Appl. No.: 10/686,866

(22) Filed: Oct. 16, 2003

(51) Int. Cl. H01L 27/108

(52) U.S. Cl. 257/306

(57) ABSTRACT

The present disclosure provides a capacitor device including a first electrode formed over a substrate and a first insulating layer formed over the first electrode. A second electrode is formed over the first insulating layer and a second insulating layer is formed over the second electrode. A third electrode is formed over the second insulating layer and a third insulating layer is formed over the third electrode. First, second and third vias are then formed. The first via couples the first electrode and a first interconnect, the second via couples the second electrode and a second interconnect and the third via couples the third electrode and the first interconnect.

### BACKGROUND

The present disclosure is related generally to the fabrication of semiconductor devices, and, more particularly, to a capacitor structure having a high unit capacitance, a method of manufacturing the structure, and a semiconductor device incorporating the structure.

Capacitors are critical components for many data manipulation and data storage applications. In general, capacitors include two conductive electrodes on opposing sides of a dielectric or other insulating layer, and they may be categorized based on the materials employed to form the electrodes. For example, in a metal-insulator-metal (MIM) capacitor, the electrodes substantially comprise metal. MIM capacitors offer the advantage of a relatively constant value of capacitance over a relatively wide range of voltages applied thereto. MIM capacitors also exhibit a relatively small parasitic resistance.

Generally, it is desirable that MIM capacitors (and others) consume as little surface area as possible to increase packing density. At the same time, capacitance values should be maximized to obtain optimum device performance, such as when employed for data retention in dynamic random access memory (DRAM) applications. However, capacitance values for a single capacitor generally decrease as the surface area of the capacitor decreases. Myriad structures have been proposed in attempt to overcome this dichotomy between minimizing capacitor structure size and maximizing capacitance values. One such example is a crown-shaped capacitor, which resembles a folded structure in which a trench is lined with a first electrode and filled with an annular shaped insulating element and an inner core electrode, thereby increasing the effective electrode contact area relative to conventional planar capacitors. However, crown capacitors and other recently proposed solutions fail to adequately address the above-discussed dichotomy, rendering capacitor devices having excessive size or exhibiting insufficient capacitance values.

Moreover, existing capacitor structures often require complex and costly manufacturing processes. For example, especially for submicron or deep submicron technologies, existing capacitor manufacturing processes are not compatible or have not been incorporated with the dual damascene processes recently developed for copper metallization in response to the difficulties encountered with etching and patterning copper elements. Dual damascene processes generally include forming a trench opening and a via opening and then simultaneously depositing metal in the trench and via openings. Dual damascene processes provide a substantially flat surface for improved lithography resolution during subsequent processing, reduced process complexity and costs, and other advantages.

Accordingly, what is needed in the art is a capacitor structure and method of manufacturing thereof that addresses the problems discussed above.

### SUMMARY

In one embodiment, the present disclosure relates to a capacitor device and a method of manufacture thereof, in which a first electrode is formed over a substrate and a first insulating layer is formed over the first electrode. A second electrode is formed over the first insulating layer and a second insulating layer is formed over the second electrode. A third electrode is formed over the second insulating layer and a third insulating layer is formed over the third electrode. First, second and third vias are then formed. The first via couples the first electrode and a first interconnect, the second via couples the second electrode and a second interconnect and the third via couples the third electrode and the first interconnect, thereby forming two capacitive elements coupled in parallel.

The present disclosure also relates to a semiconductor device including a transistor element located over a substrate and having a contact. The semiconductor device also includes a capacitor structure, including a first electrode located over the substrate, a first insulating layer located over the first electrode, a second electrode located over the first insulating layer, a second insulating layer located over the second electrode and a third electrode located over the second insulating layer. A dielectric layer is located over the transistor element and the capacitor element. A first interconnect is located over the dielectric layer, coupled to the first electrode by a first via, and coupled to the third electrode by a second via. A second interconnect is located over the dielectric layer, coupled to the second electrode by a third electrode by a third via, and coupled to the transistor contact by a fourth via. Accordingly, the capacitor structure includes two capacitive elements coupled in parallel, and may itself be coupled to the transistor element.

### BRIEF DESCRIPTION OF THE DRAWINGS

FIGS. 1 through 5 illustrate sectional views of various stages of an embodiment of a method of manufacturing a semiconductor device according to aspects of the present disclosure.

FIG. 6 illustrates a sectional view of an embodiment of a semiconductor device constructed according to aspects of the present disclosure.

FIG. 7 illustrates a plan view of an embodiment of a capacitor device constructed according to aspect of the present disclosure.

### DETAILED DESCRIPTION

The present disclosure is related generally to the fabrication of semiconductor. devices, and, more particularly, to a capacitor structure having a high unit capacitance, a method of manufacturing the structure and a semiconductor device incorporating the structure. It is understood, however, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

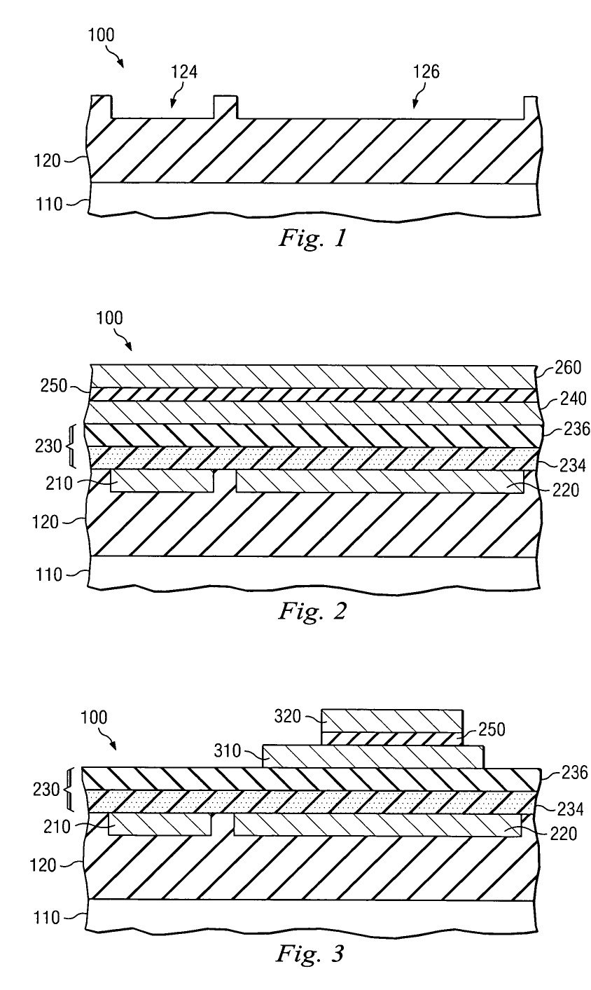

Referring to FIG. 1, illustrated is a sectional view of one embodiment of a semiconductor device 100 in an intermediate stage of manufacture according to aspects of the present disclosure. The semiconductor device 100 includes a substrate 110 which may include transistors and other active and passive logic devices as known in the art.

An insulating layer 120 is formed over the substrate 110 to a thickness that may range between about 500 nm and about 1000 nm, although other thicknesses are within the scope of the present disclosure. The insulating layer 120 may comprise silicon oxide, phosphosilicate glass (PSG), tetraethylorthosilane (TEOS) and/or low-k dielectric materials such as spin on dielectrics, polymer materials and fluorinated oxides, and may be doped with boron, phosphorous and/or other impurities. The insulating layer 120 may be patterned to form trenches 124, 126 using conventional or future-developed photolithographic and etching procedures. In one embodiment, the insulating layer 120 may be patterned as part of a dual-damascene process that may be employed in existing fabrication procedures. The trenches 124, 126 may have a depth ranging between about 200 nm and about 700 nm.

Referring to FIG. 2, illustrated is a sectional view of the semiconductor device 100 shown in FIG. 1 in a subsequent stage of manufacture. A contact 210 is formed over the substrate 110, such as in the opening 124, and contemplates a contact for the conventional or future-developed logic devices formed in the substrate 110. However, it is intended that the present disclosure does not limit the specific interconnection of the logic devices to each other or to a capacitor device subsequently formed according to aspects of the present disclosure. Those skilled in the art will recognize that there are myriad applications, structures, device layouts and interconnection schemes in which an embodiment of a capacitor device of the present disclosure may be implemented. Accordingly, for the purpose of clarity and brevity, additional details of 4 the logic devices and their interconnection are not illustrated or further described herein.

A first capacitor electrode 220 is also formed over the substrate 110, such as in the opening 126. There are myriad processes by which the contact 210 and the first capacitor electrode 220 may be formed, such as single damascene processes and other conventional or future-developed processes. In one embodiment, the contact 210 and the first capacitor electrode 220 may be formed by the blanket or selective deposition of a copper layer to fill the openings 124, 126 in the insulator layer 120, followed by a planarizing process, such as chemical-mechanical-planarizing (CMP) or a plasma etch-back.

The semiconductor device 100 also includes a first insulating layer 230 formed over the substrate 110, the contact 210 and the first capacitor electrode 220. The first insulating layer 230 may include more than one layer. For example, in the embodiment shown in FIG. 2, the first insulator layer 230 includes an etch stop layer 234 and an insulation layer 236. The etch stop layer 234 may be a conventional etch stop layer to set the end point of subsequent etching processes. The etch stop layer 234 may also or alternatively be employed as a barrier to diffusion during subsequent processing. Although not limited by the present disclosure, the etch stop layer 234 may comprise silicon carbide, silicon nitride or silicon oxynitride (SiON), may be formed by plasma enhanced chemical vapor deposition (PECVD) or low pressure chemical vapor deposition (LPCVD), and may have a thickness ranging between about 30 nm and about 150 nm. In an embodiment in which the etch stop layer 234 comprises silicon carbide, the etch stop layer 234 may be formed by PECVD employing a process chemistry comprising trimethylsilane. The insulation layer 236 may comprise TEOS or spin-on glass (SOG), may also be formed by PECVD or LPCVD, and may have a thickness ranging between about 30 nm and about 150 nm.

A conductive layer 240 is formed over the first insulator layer 230. The conductive layer 240 may comprise tungsten, tungsten silicide, aluminum, titanium, titanium nitride and combinations thereof, and may be formed by CVD, sputtering or other procedures. In one embodiment, the conductive layer 240 may include a stack of two or more layers, such as a titanium nitride/titanium/titanium nitride stack or a titanium nitride/tungsten stack. Although not limited by the present disclosure, the conductive layer 240 may have a thickness ranging between about 30 nm and about 200 nm.

A second insulating layer 250 is then formed over the conductive layer 240, possibly to a thickness ranging between about 15 nm and about 100 nm. The second insulating layer 250 may include one or more layers comprising TEOS, SiON, Si₃N₄, TiO₂, Ta₂O₅ and/or barium strontium titanate (BST), and may be formed by PECVD or other processes.

Another conductive layer 260 is then formed over the second insulating layer 250, possibly to a thickness ranging between about 30 nm and about 100 nm. The conductive layer 260 may comprise tungsten, tungsten silicide, aluminum, titanium, titanium nitride and combinations thereof, and may be formed by CVD, sputtering or other procedures. In one embodiment, the conductive layer 260 may include a stack of two or more layers, such as a titanium nitride/titanium/titanium nitride stack or a titanium nitride/tungsten stack. Moreover, the conductive layer 260 may be substantially similar in composition and fabrication to the previously formed conductive layer 240. In one embodiment, two or more of the contact 210, the first capacitor electrode 220, the insulating layers 230, 250 and the conductive layers 240, 260 may be formed without removing the substrate 110 from the process chamber, such as in an in-situ process.

Referring to FIG. 3, illustrated is a sectional view of the semiconductor device 100 shown in FIG. 2 in a subsequent stage of manufacture, in which one or more etching processes have been employed to define a second capacitor electrode 310 and a third capacitor electrode 320. In the embodiment shown in FIG. 3, a first etching process has been employed to define the second capacitor electrode 310, which may include the deposition and patterning of a photoresist layer which is employed as a mask during the etching process and subsequently stripped, such as by wet stripping or plasma ashing. The etching process may be a dry etch, a wet etch or a reactive ion etch (RIE). The third capacitor electrode 320 may be formed by similar processes, although a second photoresist mask may be employed to provide a different geometry for the third capacitor electrode 320 compared to the second capacitor electrode 310. The second etching process employed to define the third capacitor electrode 320 may also be employed to remove portions of the second insulating layer 250, such that the second insulating layer 250 may have a footprint that is substantially similar to that of the third capacitor electrode 320.

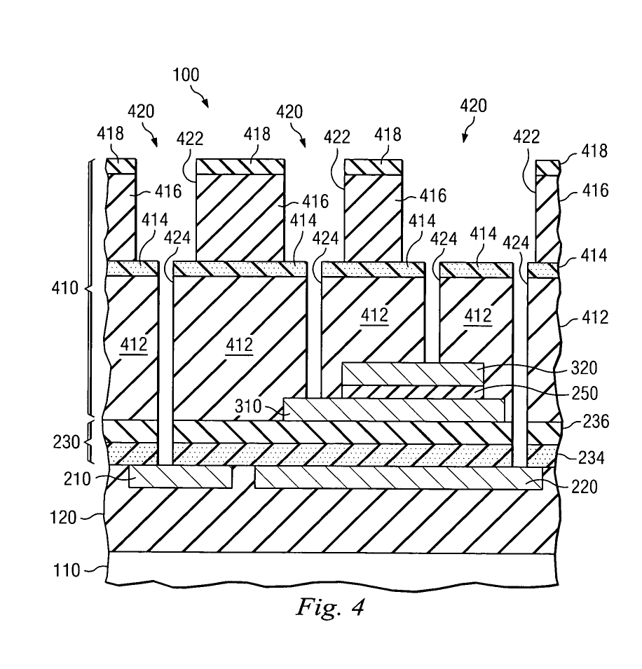

Referring to FIG. 4, illustrated is a sectional view of the semiconductor device 100 shown in FIG. 3 in a subsequent stage of manufacture according to aspects of the present disclosure. A third insulating layer 410 is formed over the second insulating layer 230, the second capacitor electrode 310 and the third capacitor electrode 320. The third insulating layer 410 may include several layers, at least one of which may also be employed as an interlayer or intermetal dielectric layer in an interconnect structure formed over the logic devices previously formed in the substrate 110.

For example, in the embodiment shown in FIG. 4, the third insulating layer 410 includes a lower dielectric layer 412, an etch stop layer 414, an upper dielectric layer 416 and a hard mask or barrier layer 418. The upper and lower dielectric layers 416, 412 may comprise TEOS, SOG, or a polymer dielectric material (low k material) and may have a thickness ranging between about 500 nm and about 1200 nm. The etch stop layer 414 and the barrier layer 418 may comprise silicon nitride or silicon carbide and may have a thickness ranging between about 30 nm and about 120 nm.

After the third insulating layer 410 is deposited, one or more etch processes are employed to form openings 420 therein. In the embodiment shown in FIG. 4, the openings 420 each include a trench portion 422 and a via portion 424, such that dual damascene processes may be employed for their formation. As such, two or more photoresist masks may be employed during the dual damascene etching process, wherein one photoresist mask may be employed to form the trench portions 422 and a second photoresist mask may be employed to form the via portions 424. The present disclosure does not limit the order in which the trench and via portions 422, 424 are formed, such that the trench portions 422 may be formed before the via portions 424, or the via portions 424 may be formed before the trench portions 422. The etching process(es) employed to form the openings 420 may include an anisotropic etch, which may be achieved by a wet etching process, a dry etching process or RIE. As also shown in FIG. 4, one or more of the openings 420 may include more than one via portion 424.

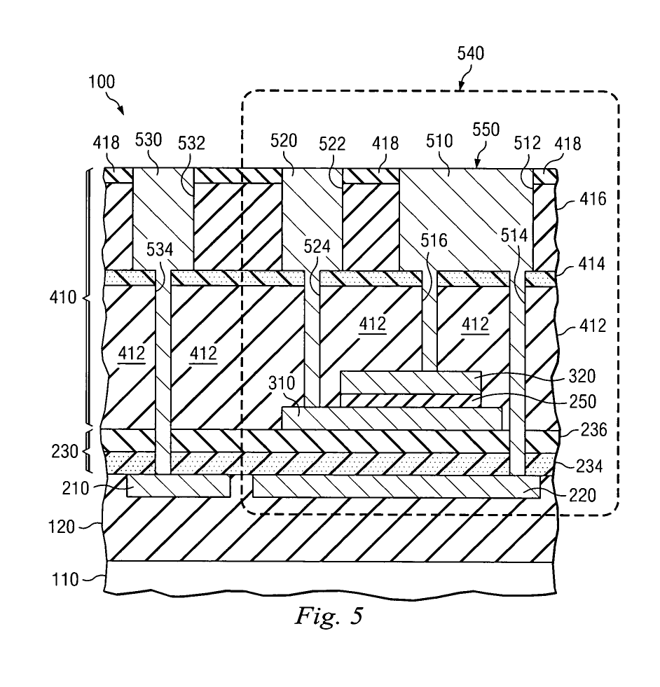

Referring to FIG. 5, illustrated is a sectional view of the semiconductor device 100 shown in FIG. 4 in a subsequent stage of manufacture according to aspects of the present disclosure. A conductive material is formed within the openings 420 to form conductors 510, 520, 530. The conductor 510 electrically couples the first capacitor electrode 220 and the third capacitor electrode 320. That is, the conductor 510 includes a trench portion or interconnect 512 above the dielectric layer 412 and etch stop layer 414, a first via portion 514 coupling the trench portion 512 and the first capacitor electrode 220 and a second via portion 516 coupling the trench portion 512 and the third capacitor electrode 320. Although in the embodiment shown in FIG. 5 the conductor 510 directly couples the first capacitor electrode 220 and the third capacitor electrode 320, such coupling may also be indirect, such as in embodiments in which adhesion layers or diffusion barrier layers are employed. In a similar manner, the conductor 520 includes a trench portion 522 and a via portion 524 coupling the trench portion 522 and the second capacitor electrode 310. The conductor 530 includes a trench portion 532 and a via portion 534 coupling the trench portion 532 and the contact 210.

The completion of the conductors 510, 520 may substantially complete a capacitor device 540 that, in one embodiment, includes the conductors 510, 520, the insulating layers 230, 250, 412, 416 and the electrodes 220, 310, 320. The first capacitor electrode 220 and the second capacitor electrode 310 sandwich the first insulating layer 230 to form a first capacitive element. The second capacitor electrode 310 and the third capacitor electrode 320 sandwich the second insulating layer 250 to form a second capacitive element. Moreover, the conductors 510, 520 form first and second ports of the capacitor device 540, wherein the first and second capacitive elements are coupled in parallel between the first and second ports. By coupling the first and second capacitive elements in parallel, the total capacitance of the capacitor device 540 may be determined by summing the individual capacitance values of the first and second capacitive elements. In one embodiment, the total capacitance of the capacitor device 540 may range between about 1.3 fF/μm² and about 2.0 fF/ pm . In a more specific embodiment, the total capacitance of the capacitor device 540 may be about 1.5 fF/μm². Moreover, as discussed above, such increased capacitance values per unit area (unit capacitance) may be achieved with existing process technology, including dual damascene processes. Accordingly, aspects of the present disclosure may be readily implemented into existing device fabrication with little or no complexity, and with little impact to fabrication time and costs.

As in the embodiment shown in FIG. 5, the conductors 510, 520, 530 may be dual damascene structures, wherein conductive material may be simultaneously deposited within the trench portions 422 and the via portions 424 of the openings 420 of FIG. 4. Of course, the present disclosure is not so limited. For example, although not illustrated as such, the conductive material forming the via portions 514, 516 of the conductor 510 may be deposited in a process step separate from the deposition of the conductive material forming the trench portion 512 of the conductor 510. The material forming the conductors 510, 520, 530 may comprise copper, aluminum, gold, tungsten or other materials, and may be deposited by PVD, CVD, electroplating or combinations thereof. Moreover, one or more of the conductors 510, 520, 530 may include more than one layer. For example, a diffusion barrier comprising tantalum or tantalum nitride may be deposited before the bulk conductive material is deposited. The semiconductor device 100 may subsequently be planarized, such as by CMP or an etch-back process, to provide a substantially planar surface 550.

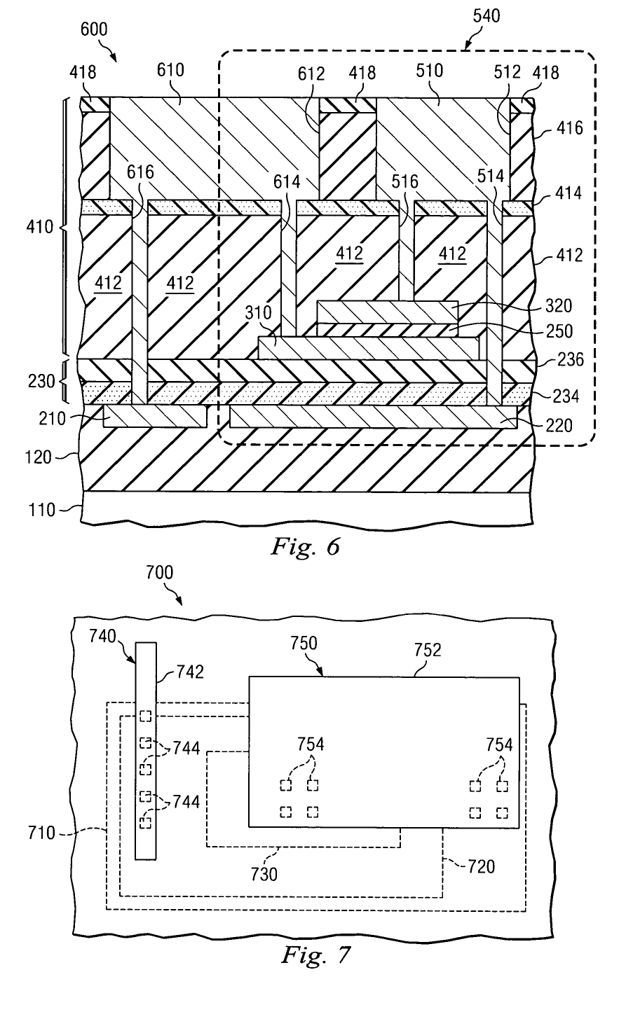

Referring to FIG. 6, illustrated is a sectional view of another embodiment of a semiconductor device 600 constructed according to aspects of the present disclosure. The semiconductor device 600 may be substantially similar to the semiconductor device 100 shown in FIG. 5, with the exception of the interconnection of the contact 210 and the capacitor device 540. In the embodiment shown in FIG. 5, the capacitor device 540 may be connected to one or more of the logic device(s) formed in the substrate 110, such as contemplated by the contact 210, by circuitry other than that shown in FIG. 5. However, in the embodiment shown in FIG. 6, the dual damascene or other process(es) employed to form the conductors 510, 520, 530 may be employed to form a conductor 610 that includes a trench portion 612, a first via 614 coupling the trench portion 612 and the second capacitor electrode 310 and a second via 616 coupling the trench portion 612 and the contact 210. As such, the capacitor device 540 may be coupled to the logic device(s) formed in the substrate 110 without the need for additional circuitry. The conductor 610 may be similar in composition and manufacture to the conductors 510, 520, 530 of FIG. 5.

Referring to FIG. 7, illustrated is a plan view of an embodiment of a capacitor device 700 constructed according to aspects of the present disclosure. The capacitor device 700 may be similar to the capacitor device 540 shown in FIG. 5. The capacitor device includes a first capacitor electrode 710, a second capacitor electrode 720 formed over the first capacitor electrode 710 and a third capacitor electrode 730 formed over the second capacitor electrode 720. The first and second capacitor electrodes 710, 720 form a first capacitive element and the second and third capacitor electrodes 720, 730 form a second capacitive element. A first interconnect structure 740 includes a trench portion 742 over the second capacitor electrode 720 and via portions 744 coupling the second capacitor electrode 720 and the trench portion 742. A second interconnect structure 750 includes a trench portion 752 over the electrodes 710, 720, 730 and via portions 754. The via portions 754 couple the first capacitor electrode 710 and the third capacitor electrode 730 to the trench portion 752, such that the first and second capacitive elements are coupled in parallel between interconnect structures 740, 750.

As shown in FIG. 7, the first capacitor electrode 710 may have a larger surface area than the surface area of the second capacitor electrode 720, and the second capacitor electrode 720 may have a larger surface area that the surface area of the third capacitor electrode 730. Moreover, the perimeter of the first capacitor electrode 710 may envelope the perimeter of the second capacitor electrode 720, and the perimeter of the second capacitor electrode 720 may envelope the perimeter of the third capacitor electrode 730. For example, no portion of the second capacitor electrode 720 may extend laterally outside of the perimeter of the first capacitor electrode 710. As such, the size of the capacitor device 700 may be relatively compact while still achieving the increased unit capacitance values discussed above with reference to FIG. 5.

The present invention has been described relative to a preferred embodiment. Improvements or modifications that become apparent to persons of ordinary skill in the art only after reading this disclosure are deemed within the spirit and scope of the application. It is understood that several modifications, changes and substitutions are intended in the foregoing disclosure and in some instances some features of the invention will be employed without a corresponding use of other features. Accordingly, it is appropriate that the appended claims be construed broadly and in a manner consistent with the scope of the invention.

1. A capacitor device, comprising:
a first electrode located over a substrate and connected to a first interconnect;
a first insulating layer located over the first electrode;
a second electrode located over the first insulating layer and connected to a second interconnect;
a second insulating layer located over the second electrode; and
a third electrode located over the second insulating layer and connected to the first interconnect.

2. The capacitor device recited in claim 1 wherein the third electrode is located over the first and second electrodes.

3. The capacitor device recited in claim 1 further comprising a third insulating layer located over the third electrode, wherein the first and second interconnects are located over the third insulating layer.

4. The capacitor device recited in claim 1 wherein:
the first electrode and the first interconnect are connected by a first via;
the second electrode and the second interconnect are connected by a second via; and
the third electrode and the first interconnect are connected by a third via.

5. The capacitor device recited in claim 4 wherein at least one of the first, second and third vias and at least one of the first and second interconnects are collectively a dual-damascene structure.

6. The capacitor device recited in claim 1 wherein the first insulating layer includes an insulation layer and an etch stop layer located over the insulation layer.

7. The capacitor device recited in claim 1 wherein a first perimeter of the first electrode envelopes a second perimeter of the second electrode.

8. The capacitor device recited in claim 7 wherein the second perimeter envelopes a third perimeter of the third electrode.

9. The capacitor device recited in claim 1 wherein the first electrode comprises copper.

10. The capacitor device recited in claim 1 wherein the second and third electrodes each comprise a same one selected from the group consisting of:
tungsten;
tungsten silicide;
aluminum;
titanium; and
titanium nitride.

11. The capacitor device recited in claim 1 wherein the second and third electrodes each include a plurality of conductive layers.

12. The capacitor device recited in claim 1 wherein a total unit capacitance of the capacitor device ranges between about 1.3 fF/μm² and about 2.0 fF/μm².

13. The capacitor device recited in claim 1 wherein a total unit capacitance of the capacitor device is about 1.5 fF/μm².

14. A method of manufacturing a capacitor device, comprising:
forming a first interconnect over and coupled to a first electrode;
coupling the first interconnect to a second electrode formed over the first electrode; and
forming a second interconnect over and coupled to a third electrode, the third electrode interposing the first and second electrodes.

15. The method recited in claim 14 further comprising:
forming a first insulating layer interposing the first and third electrodes;
forming a second insulating layer interposing the second and third electrodes; and forming a third insulating layer interposing the second electrode and the first and second interconnects.

16. The method recited in claim 15 wherein the first interconnect is a dual-damascene structure having:
a trench portion over the third insulating layer; and
a via portion extending through at least the first and third insulating layers.

17. The method recited in claim 15 wherein forming the first insulating layer includes forming an insulation layer and forming an etch stop layer over the insulation layer.

18. The method recited in claim 14 wherein at least one of the first, second and third electrodes comprises a plurality of conductive layers.

19. A semiconductor device, comprising:
a transistor element located over a substrate and having a contact;
a capacitor element, including:
a first electrode located over the substrate;
a first insulating layer located over the first electrode;
a second electrode located over the first insulating layer;
a second insulating layer located over the second electrode; and
a third electrode located over the second insulating layer;
a dielectric layer located over the transistor element and the capacitor element;
a first interconnect located over the dielectric layer, coupled to the first electrode by a first via, and coupled to the third electrode by a second via; and
a second interconnect located over the dielectric layer, coupled to the second electrode by a third electrode by a third via, and coupled to the transistor contact by a fourth via.

20. The semiconductor device recited in claim 19 wherein the first interconnect and the first and second vias are collectively a dual-damascene structure

21. The semiconductor device recited in claim 19 wherein the second interconnect and the third and fourth vias are collectively a dual-damascene structure.

22. The semiconductor device recited in claim 19 wherein the first insulating layer includes an insulation layer and an etch stop layer located over the insulation layer.

23. The semiconductor device recited in claim 19 wherein the first electrode comprises copper.

24. The semiconductor device recited in claim 19 wherein the second and third electrodes each comprise a same one selected from the group consisting of:
tungsten;
tungsten silicide;
aluminum;
titanium; and
titanium nitride.

25. The semiconductor device recited in claim 19 wherein the second and third electrodes each include a plurality of conductive layers.
